(19) United States
(12) Patent Application Publication
(10) Pub. No.: US 2026/0302831 A1
(43) Pub. Date: Oct. 1, 2026

(54) ENERGY HARVESTING APPARATUS AND METHOD

(71) Applicant: Nditive3D Inc., St. John's (CA)

(72) Inventors: Seyedfakhreddin Nabavi, St. John's (CA); Salar Salahi, St. John's (CA)

(21) Appl. No.: 19/093,456

(22) Filed: Mar. 28, 2025

(51) Int. Cl. H02J 50/00; H02J 50/30; H02N 2/18; H10F 19/80

(52) U.S. Cl. CPC H02J 50/001; H02J 50/005; H02J 50/30; H02N 2/186; H10F 19/80

(57) ABSTRACT

An energy harvester, including a flexible layered sheet having an upper face on an upper side and a lower face opposite the upper face on a lower side. The flexible layered sheet includes a first photovoltaic layer at the upper end, a second photovoltaic layer at the lower end, and first and second piezoelectric layers between the first and second photovoltaic layers whereby vibration of the energy harvester results in the generation of electricity and exposure of the energy harvester to light results in the generation of electricity.

### TECHNICAL FIELD

The disclosure relates to energy harvesting, and particularly to an energy harvester to harvest energy from both vibrations and light.

### BACKGROUND

U.S. Pat. No. 11,799,398 to Zhang et al. (“Zhang”) purports to disclose several types of piezoelectric MEMS vibration energy harvesters as well as methods of fabricating the vibration energy harvesters. Zhang purports to disclose that the vibration energy harvesters generally comprise a serpentine structure having a central longitudinal axis; a piezoelectric film deposited on a surface of the serpentine structure; a central mass located at a mid-portion of the central longitudinal axis; two lateral masses positioned at opposing corners of the serpentine structure; anchor points at two other opposing corners of the serpentine structure; and upper and lower electrode layers. Zhang purports to disclose that the energy harvesters have a 180 degree rotational symmetry about the central mass and when the serpentine structure experiences a strain, the piezoelectric film generates a voltage. Zhang purports to disclose that the geometry of the energy harvesters allows for lower frequency and wider bandwidth operation as well as higher power density.

### SUMMARY

According to an aspect, there is provided an energy harvester, comprising a flexible layered sheet having an upper face on an upper side and a lower face opposite the upper face on a lower side, the flexible layered sheet including a first photovoltaic layer at the upper end, a second photovoltaic layer at the lower end, and first and second piezoelectric layers between the first and second photovoltaic layers, whereby vibration of the energy harvester results in the generation of electricity and exposure of the energy harvester to light results in the generation of electricity.

In some examples, the energy harvester further comprises a first adhesive layer between the first photovoltaic layer and the first piezoelectric layer, a second adhesive layer between the first piezoelectric layer and the second piezoelectric layer, and a third adhesive layer between the second piezoelectric layer and the second photovoltaic layer.

In some examples, the adhesive layers are formed to produce a desired operating frequency and flexibility of the energy harvester by controlling Young's modulus of the adhesive layers through the selection of a mixture of different materials or the temperature, pressure and duration of curing.

In some examples, thicknesses and porosity of the adhesive layers are selected to produce a desired flexibility of the adhesive layers by increasing the porosity and reducing the thickness to produce greater flexibility and lower operating frequency and reducing the porosity and increasing the thickness to produce reduced flexibility and higher operating frequency.

In some examples, the first and/or second piezoelectric layers are operable mode 33.

In some examples, the first and/or second piezoelectric layers are operable mode 31.

In some examples, the energy harvester further comprises a protective layer surrounding the sheet to protect from environmental impacts and increase durability.

In some examples, the energy harvester comprises both transparent and non-transparent electrodes, the transparent electrodes arranged to pass light to the active layer, the non-transparent electrodes arranged to reflect light to the active layer.

In some examples, the energy harvester comprises organic materials, the organic materials deposited by thermal evaporation or solution-based processes.

In some examples, materials used to construct the energy harvester are selected such that the energy harvester is light and flexible, incorporating a polymer-based or plastic layer serving as a substrate.

In some examples, the energy harvester is mounted to a base and spaced from a reflective outside surface of the base, to receive reflected light from the reflective outside surface on an underside of the harvester that is directed towards the reflective outside surface.

In some examples, the base is a helmet or a clip.

In some examples, the energy harvester is integrated with CMOS circuitry to rectify and regulate harvested voltage and/or current.

According to another aspect, there is provided an energy harvester system comprising an energy harvester secured to a fixture and coupled to a power management system.

In some examples, the energy harvester is secured at one end thereof to the fixture while the opposing end is unsecured to move freely.

According to another aspect, there is provided an array comprising an energy harvester system with a plurality of energy harvesters secured to the fixture and coupled to the power management system.

According to another aspect, there is provided a helmet comprising an energy harvester mounted to a helmet.

According to another aspect, there is provided an assembly comprising an energy harvester mounted to a base, the base being U-shaped and formed of a material with elastic properties and shaped to be fitted to a wearer's shoulder.

According to another aspect, there is provided a shoe comprising an energy harvester secured at one end thereof to a body of the shoe by laces of the shoe while an opposite end is unsecured to move freely.

According to another aspect, there is provided a shoe comprising an energy harvester secured at each of first and second opposing ends to a body of the shoe.

### BRIEF DESCRIPTION OF THE DRAWINGS

The drawings included herewith are for illustrating various examples of systems, methods, and apparatus of the present specification. In the drawings:

FIG. 1 is a side perspective cross sectional view of an example energy harvester system;

FIG. 2 is a schematic diagram of an example energy system including the energy harvester system of FIG. 1;

FIG. 3A is a side view of a first example of a photovoltaic layer;

FIG. 3B is a side view of a second example of a photovoltaic layer;

FIG. 4A is a top perspective view of a first example of a piezoelectric layer;

FIG. 4B is a top perspective view of a second example of a piezoelectric layer;

FIG. 5A is a side view of a first step of a fabrication process;

FIG. 5B is a side view of a second step of the fabrication process of FIG. 5A;

FIG. 5C is a side view of a third step of the fabrication process of FIG. 5A;

FIG. 5D is a side view of a fourth step of the fabrication process of FIG. 5A;

FIG. 5E is a side view of a fifth step of the fabrication process of FIG. 5A;

FIG. 5F is a side view of a sixth step of the fabrication process of FIG. 5A;

FIG. 5G is a side view of a seventh step of the fabrication process of FIG. 5A;

FIG. 6 is a top perspective view of an example energy harvester mounted to a headwear device;

FIG. 7 is top perspective view of an example array of energy harvesters;

FIG. 8 is a top perspective view of an example energy harvester assembly including an energy harvester mounted to a shoulder-mount base;

FIG. 9 is a side view of a user wearing the headwear device of FIG. 6 and two of the energy harvester assemblies of FIG. 8;

FIG. 10A is a first example of an energy harvester mounted to a shoe; and

FIG. 10B is a second example of an energy harvester mounted to a shoe.

### DETAILED DESCRIPTION

Various apparatuses, assemblies, or processes will be described below to provide an example of an embodiment of each claimed invention. No embodiment described below limits any claimed invention and any claimed invention may cover apparatuses, assemblies, or processes that differ from those described below. The claimed inventions are not limited to apparatuses, assemblies, or processes having all of the features of any one apparatus, assembly, or process described below or to features common to multiple or all of the apparatuses, assemblies, or processes described below. It is possible that an apparatus, assembly, or process described below is not an embodiment of any claimed invention. Any invention disclosed in an apparatus, assembly, or process described below that is not claimed in this document may be the subject matter of another protective instrument, for example, a continuing patent application, and the applicants, inventors, or owners do not intend to abandon, disclaim, or dedicate to the public any such invention by its disclosure in this document. Like reference numbers represent corresponding parts throughout.

The present disclosure relates to an energy harvester and/or to the design, fabrication, and/or implementation of the energy harvester. The energy harvester is capable of harvesting energy from its environment and/or usage, e.g., from vibration and/or light. In some embodiments, the energy harvester is a multi-source energy harvester. Energy harvestable by the energy harvester may be classified as light energy (e.g., solar) and vibration energy. The energy harvester is capable of harvesting energy from both or either of light (e.g., solar), and vibrations.

The energy harvester harvests energy and converts it into electrical power, e.g., for low-power electronic devices. This helps reduce dependence on energy storage devices such as batteries, which helps reduce or eliminate the need to integrate, replace, and or recharge an energy storage device. In some examples, the energy harvester is a lightweight energy harvester. In some embodiments, the energy harvester is used to power small and/or wireless devices. In some embodiments, the energy harvester is used to power Internet of Things (IoT)-enabled devices, wearable electronics, and/or portable monitoring systems. In some embodiments, the energy harvester is used to power a microsystem that can operate with the consumption of nano amperes of electricity (i.e., <100 nano amperes), e.g., a temperature sensor with a power consumption of 60 nW at an input voltage of 0.8 V (Naveed and J. Dix, “An Ultra-Low-Power 0.8 V, 60 nW Temperature Sensor for Battery-Less Wireless Sensor Networks,” J. Low Power Electron. Appl., vol. 15, no. 1, p. 1, 2025, the entirety of which is hereby incorporated by reference herein).

An alternavity type of energy to light and vibration energy is thermal energy. Thermal energy can be harvested using thermoelectric conversion, wherein the temperature difference between two materials with different Seebeck coefficients can offer electrical potential/power (see, e.g., P. Dziurdzia, “Modeling and simulation of thermoelectric energy harvesting processes,” Sustain. Energy Harvest. Technol. Present Futur. Cracow AGH Univ. Sci. Technol., pp. 109-116, 2011, the entirety of which is hereby incorporated by reference herein), and may be employed in thermocouples (see, e.g., U.S. Pat. No. 11,183,625, the entirety of which is hereby incorporated by reference herein). However, the inventors have found that thermal-based energy harvester generally require a large surface area, and generated voltage is proportional with temperature gradient and Seebeck coefficients, which result to the creation of less appealing harvesters for wearable/portable devices. Accordingly, the energy harvester disclosed herein is capable of harvesting energy from light and mechanical vibrations.

Light energy is harvested using the photovoltaic effect in solar panels. This technology can be used to create sustainable and concentrated power plants (see, e.g., H. L. Zhang, J. Baeyens, J. Degrève, and G. Cacères, “Concentrated solar power plants: Review and design methodology,” Renew. Sustain. energy Rev., vol. 22, pp. 466-481, 2013, the entirety of which is hereby incorporated by reference herein). The photovoltaic efficiency of a solar panel can be increased by integrating spectral filter and self-cleaning mechanisms in their surfaces (see, e.g., M. Sheikholeslami and Z. Khalili, “Enhancing photovoltaic solar panel performance with integration of PCM-based spectral filter and self-cleaning coating,” J. Build. Eng., vol. 94, p. 110019, 2024, the entirety of which is hereby incorporated by reference herein). Solar panels can be flexible (see, e.g., United States Patent App. Pub. No. 2019/0322376 and U.S. Pat. No. 8,512,866 , the entirety of each of which is hereby incorporated by reference herein). Plastic or polymer substrate can be used to house active materials made of organic or inorganic semiconductors or their combinations, called active materials, to convert light to electricity (see, e.g., H. Yoon, S. M. Kang, J.-K. Lee, and M. Choi, “Hysteresis-free low-temperature-processed planar perovskite solar cells with 19.1% efficiency,” Energy Environ. Sci., vol. 9, no. 7, pp. 2262-2266, 2016, the entirety of which is hereby incorporated by reference herein). The inventors have found that these may be used in an energy harvester which can be readily formed to the different shapes, and are lightweight. However, flexible photovoltaic harvesters can exhibit lower efficiency compared to rigid counterparts (see, e.g., Y. Gao et al., “Flexible perovskite solar cells: From materials and device architectures to applications,” ACS Energy Lett., vol. 7, no. 4, pp. 1412-1445, 2022 and S. S. Shin et al., “High-performance flexible perovskite solar cells exploiting Zn2SnO4 prepared in solution below 100 °C,” Nat. Commun., vol. 6, no. 1, p. 7410, 2015, the entirety of each of which is hereby incorporated by reference herein).

Mechanical vibration energy is harvested by a conversion mechanism. In some embodiments, mechanical vibration energy is harvested by electromagnetic, electrostatic, and/or piezoelectric conversion mechanisms. The Mechanical vibration can originate from various sources, e.g., human motion, machinery operation, structural vibrations, vehicular movement, wind/water-induced oscillations, and acoustic waves. Some conversion mechanisms, such as wind turbine generators (see, e.g., H. Polinder, J. A. Ferreira, B. B. Jensen, A. B. Abrahamsen, K. Atallah, and R. A. McMahon, “Trends in wind turbine generator systems,” IEEE J. Emerg. Sel. Top. power Electron., vol. 1, no. 3, pp. 174-185, 2013, the entirety of which is hereby incorporated by reference herein), require permanent magnets and coils, imposing limitations on making small scale and flexible vibration energy harvesters (see, e.g., U.S. Pat. No. 11,309,808 , the entirety of which is hereby incorporated by reference herein). Electrostatic conversion can be used to convert vibration into electricity, using an external bias voltage to create electrostatic force between two electrodes separated by an airgap and generating electricity when vibrations alter the relative positions of the electrodes, and devices can be constructed by micromachining processes (see, e.g., United States Patent App. Pub. No. 2024/0388224, the entirety of which is hereby incorporated by reference herein). However, the requirement of a bias voltage or electrets (pre-charged dielectrics between two electrodes) (see, e.g., S. Boisseau, G. Despesse, T. Ricart, E. Defay, and A. Sylvestre, “Cantilever-based electret energy harvesters,” Smart Mater. Struct., vol. 20, no. 10, p. 105013, 2011, the entirety of which is hereby incorporated by reference herein) minimize the versatility of such an energy harvester to create easy-fabricated and standalone vibration energy harvesters.

The inventors have found that materials with piezoelectric effect are useful in creation of efficient vibration energy harvesters at relatively small scale, e.g., from a few micrometres to a few centimetres, without requiring external bias voltage. An energy harvester can use piezoelectric materials with high efficiency, such as Aluminum scandium nitride (ScAIN) (see, e.g., P. M. Mayrhofer et al., “ScAIN MEMS cantilevers for vibrational energy harvesting purposes,” J. Microelectromechanical Syst., vol. 26, no. 1, pp. 102-112, 2016, the entirety of which is hereby incorporated by reference herein). An energy harvester can use a geometry selected to expand efficiency and/or bandwidth (see, e.g., U.S. Pat. No. 11,799,398 , the entirety of which is hereby incorporated by reference herein). Ceramic based piezoelectric materials may be used, e.g., lead zirconate titanate (PZT), aluminum nitride (AlN), zinc oxide (ZnO). Alternatively, or additionally, piezoelectric polymers such as Polyvinylidene Fluoride (PVDF) and its copolymers, may be used, e.g., to make flexible vibration energy harvesters. A multi-layer PVDF has been used in shoe insoles to collect vibration energy from human movement (see, e.g., J. Kymissis, C. Kendall, J. Paradiso, and N. Gershenfeld, “Parasitic power harvesting in shoes,” in Digest of papers. Second international symposium on wearable computers (Cat. No. 98EX215), 1998, pp. 132-139, the entirety of which is hereby incorporated by reference herein). Flexible based piezoelectric polymer, PVDF, has been used to harvest energy from wind and rain drops (see, e.g., D. Vatansever, R. L. Hadimani, T. Shah, and E. Siores, “An investigation of energy harvesting from renewable sources with PVDF and PZT,” Smart Mater. Struct., vol. 20, no. 5, p. 55019, 2011, the entirety of which is hereby incorporated by reference herein). Fabrication of a flexible vibration energy harvester piezoelectric polymer materials can involve deposition on the surface of a flexible substrate, such as elastomer, preferably Polydimethylsiloxane (PDMS), through spin coating, drop casting or etc. A flexible layer can serve as a supporter (see, e.g., H. Mutsuda, Y. Tanaka, R. Patel, and Y. Doi, “Harvesting flow-induced vibration using a highly flexible piezoelectric energy device,” Appl. Ocean Res., vol. 68, pp. 39-52, 2017, the entirety of which is hereby incorporated by reference herein).

The inventors have discovered that a dual energy harvesting system capable of harnessing energy from both light and vibration results in efficient and robust power generation. The inventors have developed an efficient and robust power generation solution capable of harnessing energy from both light and vibration. In some embodiments, the energy harvester is a flexible energy harvester and made of a composite of flexible materials. In some embodiments, the energy harvester comprises two piezoelectric layers, whose surfaces are covered with photovoltaic layers. Multiple adhesive layers are employed to bond each layer together. The operating frequency and overall flexibility of the energy harvester can be determined by the properties of adhesive layers. The energy harvester is useable for powering small, and wireless devices, including Internet of Things (IoT)-enabled devices, wearable electronics, and portable monitoring systems.

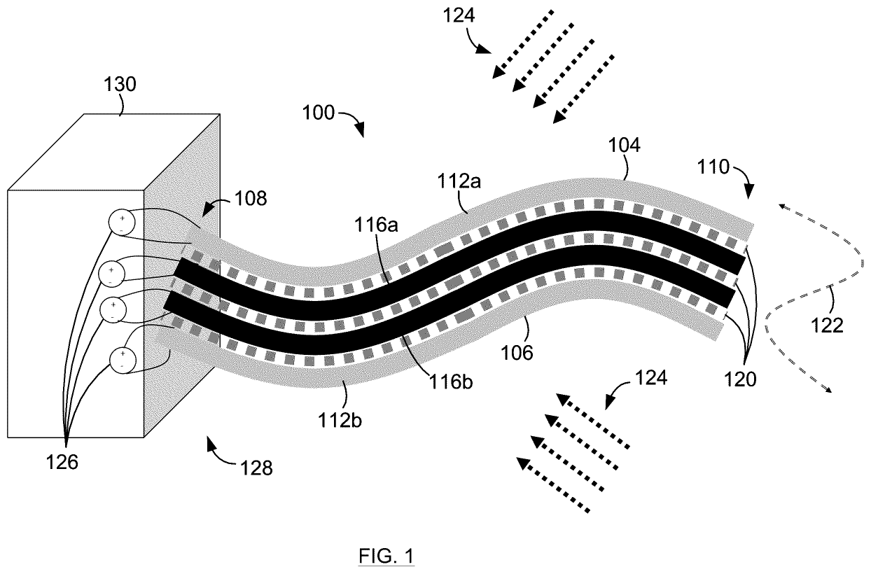

Referring to FIG. 1, illustrated is an example energy harvester 100. The example energy harvester 100 is a multi-source, flexible energy harvester. The energy harvester 100 is a layered structure. The example energy harvester 100 is a sheet with an upper face 104 and a lower face 106 opposite the upper face. The sheet extends longitudinally between a first end 108 and a second end 110 opposite the first end. The energy harvester also extends laterally between a first side and a second side opposite the first side, each of the first and second sides extending from the first end 108 to the second end 110.

The layered structure of the energy harvester 100 includes a first photovoltaic layer 112a and a second photovoltaic layer 112b. The first photovoltaic layer 112a is at an upper end of the harvester 100. The second photovoltaic layer 112b is at a lower end of the harvester 100. In some embodiments, the photovoltaic layers share one or more characteristics with one another (e.g., the same materials, the same structure, and/or the same thickness). In some embodiments, the photovoltaic layers share all characteristics with one another. In some embodiments one photovoltaic layer has one or more characteristics different from another photovoltaic layer. In the illustrated embodiment, the harvester includes two photovoltaic layers. In some embodiments, the harvester includes only two photovoltaic layers (i.e., one upper to receive light incident on the top of the harvester sheet and one lower to receive light incident on the bottom of the harvester sheet).

The energy harvester 100 also includes a first piezoelectric layer 116a and a second piezoelectric layer 116b. The first and second piezoelectric layers 116a, 116b are between the photovoltaic layers. In some embodiments, the piezoelectric layers share one or more characteristics with one another (e.g., the same materials, the same structure, and/or the same thickness). In some embodiments, the piezoelectric layers share all characteristics with one another. In some embodiments one piezoelectric layer has one or more characteristics different from another piezoelectric layer. In the illustrated embodiment, the harvester includes two piezoelectric layers. In some embodiments, the harvester includes only two piezoelectric layers. In some embodiments, the harvester includes more or less than two piezoelectric layers.

The layers 112a, 112b, 116a, and 116b are secured together. In the example illustrated, the harvester 100 includes adhesive layers 120 between adjacent layers 112a, 112b, 116a, and 116b. The example harvester 100 is a biomorph piezoelectric beam, in which the top and bottom surfaces are formed by photovoltaic layers (or by a protective coating over photovoltaic layers).

The adhesive layers 120 have a dual role. The adhesive layers attach abutting layers of the harvester 100 to one another. The adhesive layers also control operating frequency and flexibility of the entire energy harvesting system. The adhesive layer Young's modulus, a parameter that indicates flexibility, can be adjusted with controlling molecular arrangement. In some embodiments, the Young's modulus of an adhesive layer is adjusted by controlling porosity. In some embodiments, porosity is determined by curing conditions, i.e., one or more of duration, pressure and temperature. Alternatively, a mixture of multiple materials with different Young's moduli can be used. The thickness of adhesive layer can be used to control flexibility. A lower thickness leads the greater flexibility and vice versa. In some embodiments, the adhesive layers share one or more characteristics with one another (e.g., the same materials, the same curing conditions, and/or the same thickness). In some embodiments, one or more adhesive layers share all characteristics with another adhesive layer. In some embodiments one or more adhesive layers have one or more characteristics different from one or more other adhesive layers. The materials are selected to allow the harvester 100 to be readily adopted into various shapes. Accordingly, in some embodiments, the adhesive layers help to create a double-source energy harvester, and the operating frequency of the harvester can be tuned for different applications. Tuning the frequency can be done through: 1) using composite materials, and/or 2) curing parameters like temperature, duration, and pressure.

In the event of vibrations 122, such as due to human movement, wind, sea waves, etc., the harvest 100 vibrates periodically, and these vibrations are converted into electricity. At the same time, the photovoltaic layers absorb light 124 (e.g., natural sunlight or artificial light such as from lamps) and convert it into electricity. Each energy-producing layer is joined to a circuit 126 to supply electricity to the circuit 126. A circuit 126 may be coupled to only a single electricity generating layer or to more than one electricity generating layer. Accordingly, an energy harvesting system 128 comprising the harvester 100 may include a single circuit 126 or a plurality of circuits 126.

The example energy harvester 100 is anchored to a fixture 130. The circuit(s) 126 may be mounted to or integrated in the fixture 130. The energy harvester 100 is anchored to the fixture 130 at the first end 108. In some embodiments, the energy harvester 100 is only anchored at one end, leaving the other end and the sides free. This helps allow the harvester 100 to move more freely at lower frequencies to more effectively harvest energy from movement.

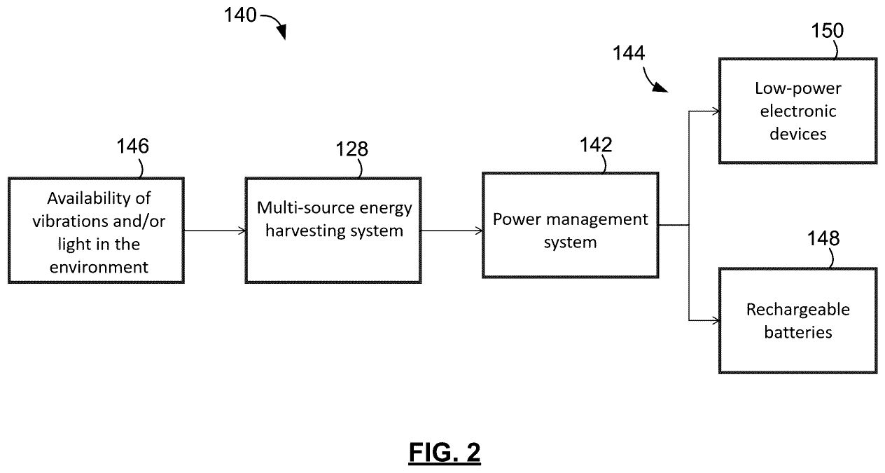

Referring now to FIG. 2, an energy system 140 is illustrated. The energy system 140 includes the energy harvesting system 128, a power management system 142, and a power user system 144. Energy 146 in the environment (vibrations and/or light) is harvested using the energy harvesting system 128. When vibrations and/or light is/are available, the corresponding photovoltaic and/or piezoelectric layers of the energy harvesting system 128 are activated and generate electricity from the relevant energy source.

The energy harvesting system 128 supplies electricity to the power management system 142. The power management system 142 rectifies and regulates the harvested electrical voltage/current for practical uses. The voltage/current supplied by the energy harvester is delivered to the power management system 142 (e.g., via the circuit(s) 126). The power management system 142 may include analog integrated circuits. In some embodiments, the system includes a full-wave or half-wave rectifier. In some embodiments, the rectifier is made of silicone, Schottky diodes, and/or diode-connected transistors. Thereafter rectifier, in some embodiments the system comprises a boost converter circuit to enlarge the harvested voltage/current. In some embodiments, a Low-dropout regulator is included to stabilize the harvested voltage and current at a selected level. In some embodiments, the power management system is implemented and fabricated using complementary metal-oxide semiconductor (CMOS) technology (e.g., where all functional blocks can be integrated efficiently into a small footprint). The rectified and regulated power by the power management system 142 is supplied to a power user system 144, such as a charge to a rechargeable battery 148 or a power supply for a low-power consumer device 150, or both.

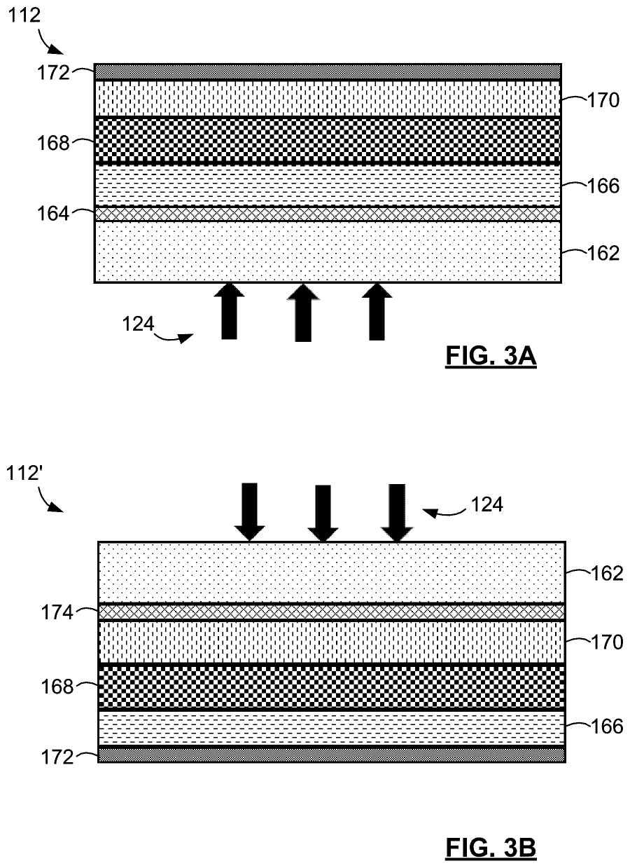

Referring now to FIGS. 3A and 3B, each photovoltaic layer 112a, 112b of the energy harvester 100 is a composite of sublayers. The employed photovoltaic layer includes a stack of multiple layers with different energy bandgaps.

A general representation of an example photovoltaic layer 112 is shown in FIG. 3A. The photovoltaic layer 112 includes a flexible and transparent layer 162. In some embodiments, the flexible and transparent layer 162 is formed of or includes Polyethylene terephthalate (PET) polyethylene naphthalate (PEN), and/or polyimide (PI). The flexible substrate 162 is coated with a thin layer 164 of transparent and electrically conductive material. In some embodiments, the layer 164 has a thickness on the order of 100 nm. In some embodiments, the layer 164 is formed of or includes Indium tin oxide (ITO). The subsequent layer is hole transfer layer (HTL) 166. In some embodiments, the HTL 166 is formed of or includes poly(3,4-ethylenedioxythiophene): poly(styrenesulfonate) (PEDOT:PSS), which may include other materials such copper(I) thiocyanate (CuSCN) depending on fabrication procedure, to exhibit better performance (see, e.g., S. Nabavi, H. Anabestani, and S. Bhadra, “Low-Power Organic LED Fabricated by a Novel Solution-Based Process for Photoplethysmography Sensing,” IEEE J. Flex. Electron., vol. 2, no. 1, pp. 34-42, 2023, the entirety of which is hereby incorporated by reference herein). The next layer is an active layer 168. The active layer 168 is highly sensitive to photon absorption. In some embodiments, the active layer 168 is or includes perovskite, a donor-acceptor blend such as poly(3-hexylthiophene) (P3HT) and phenyl-C61-butyric acid methyl ester (PCBM)-based bulk heterojunction (BHJ), copper silver bismuth iodide, and/or a combination of other suitable materials. Subsequently, an electron transfer layer (ETL) 170 is deposited. A thin layer of conductive material 172, such as aluminum (Al) forms the back electrode of the illustrated example photovoltaic layer 112. The layer 172 may also serve as a reflector to direct light back to the active layer 168. It will be appreciated that a thickness and material composition of the layer 112 and/or one or more layers in layer 112 may be varied and selected to enhance the efficiency of the photovoltaic. In some embodiments, the layer 112 includes one or more further layers.

Referring to FIG. 3B, illustrated is an alternative example photovoltaic layer 112′. Photovoltaic layer 112′ is an inverted structure. In this configuration, the photovoltaic layer 112′ absorbs light through its back electrode. A transparent back electrode 174 is deposited on a transparent substrate 162. In some embodiments, the transparent back electrode 174 is formed of or comprises Fluorine-doped tin oxide (FTO) or ITO. The back electrode 174 is followed by an ETL 170, an active layer 168, a HTL 166, and a bottom electrode 172. The bottom electrode 172 is optically non-transparent in order to reflect light back to the active layer 168.

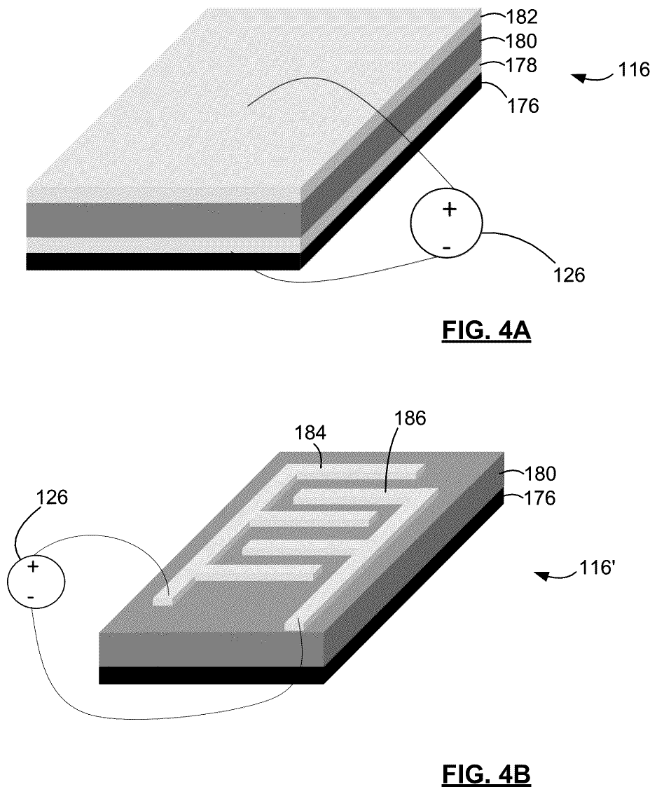

Referring now to FIGS. 4A and 4B, the piezoelectric layers can operate using the piezoelectric effect in either mode 31 or mode 33 (see, e.g., H. Miyabuchi, T. Yoshimura, S. Murakami, and N. Fujimura, “Characterization of direct piezoelectric effect in 31 and 33 modes for application to vibration energy harvester,” Jpn. J. Appl. Phys., vol. 50, no. 9S2, p. 09ND17, 2011, the entirety of which is hereby incorporated by reference herein).

Referring to FIG. 4A, the example piezoelectric layer 116 is structured to operate in mode 31. The piezoelectric layer 116 includes multiple layers, including a flexible polymer-based substrate 176, a bottom electrode 178, a polymer piezoelectric material layer 180, and a top electrode 182. In some embodiments, the bottom electrode 178 and/or the top electrode 182 is made of or comprises conductive materials such as aluminum, gold, or chrome. In some embodiments, the bottom electrode 178 and/or the top electrode 182 is approximately 100 nm thick. In some embodiments, the top electrode is identical in shape and material to the bottom electrode. In some embodiments, the polymer piezoelectric material layer 180 is made of or comprises PVDF and/or PVDF-TrFE). In some embodiments, the polymer piezoelectric material layer 180 has a thickness ranging from a few hundred nanometers to several micrometers.

Referring to FIG. 4B, an alternative example piezoelectric layer 116′ is structured to operate in mode 33. A single set of electrodes 184, 186 is formed in a common layer. The electrodes 184, 186 are positioned on the surface of the piezoelectric material layer 180. The electrodes 184, 186 are arranged in an interdigitated pattern, with each trace spaced at a specific distance from the others.

It will be appreciated that one or more substrates (e.g., of a piezoelectric layer and/or photovoltaic layer) may be omitted when a layer is formed as part of a multilayer sheet such as for harvester 100.

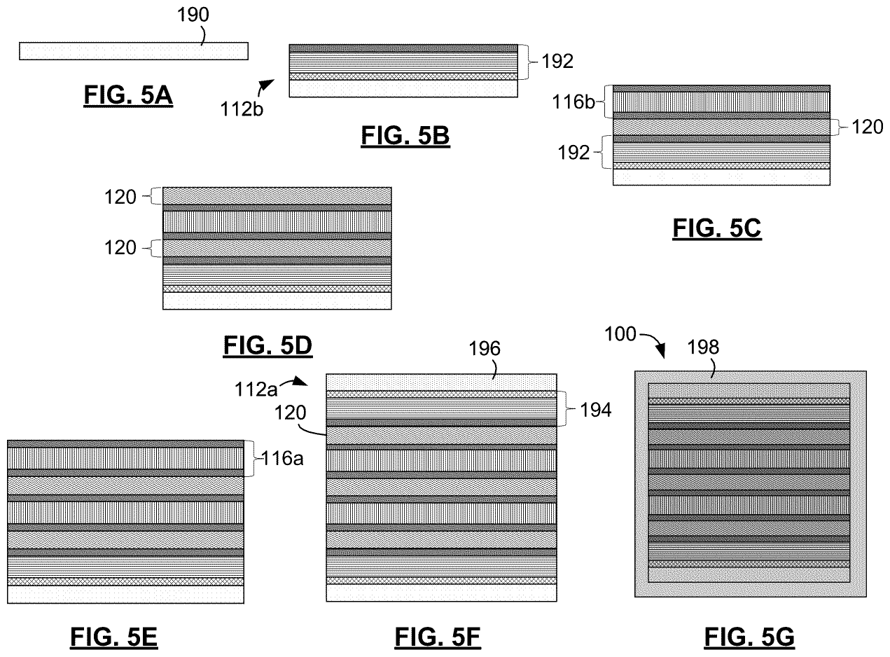

Referring now to FIGS. 5A to 5G, illustrated is a fabrication process of the energy harvester 100. In the example illustrated, the energy harvester 100 is constructed in multiple steps. Referring to FIG. 5A, the fabrication process begins with cleaning a transparent and flexible substrate for use as a bottom substrate 190. In some examples, the bottom substrate 190 is subjected to oxygen plasma treatment to enhance surface properties. Referring to FIG. 5B, after preparing the bottom substrate 190, a composite 192 of photovoltaic materials, including conductive electrodes, HTL, active layer, and ETL, is deposited on the substrate 190 to form photovoltaic layer 112b.

Referring now to FIG. 5C, an electrically insulating adhesive layer 120 is applied. The thickness and Young's modulus (flexibility) of the adhesive layer 120 are determined based on the curing method, pressure and temperature used. Polymer-based piezoelectric layer 116b, along with its associated electrodes, is then attached. Referring to FIG. 5D, in the next step, a second adhesive layer 120 is applied with controlled thickness and flexibility.

Referring to FIG. 5E, this is followed by the deposition of the piezoelectric polymer layer 116a and its associated electrodes. Referring to FIG. 5F, subsequently, an additional adhesive layer 120 is deposited, followed by placing a composite 194 of photovoltaic materials to form the top photovoltaic layer 112a. Referring to FIG. 5G, in a further step, to ensure durability and environmental protection of the energy harvesting system, the entire device is encapsulated with a thin protective layer 198 to form the energy harvester 100.

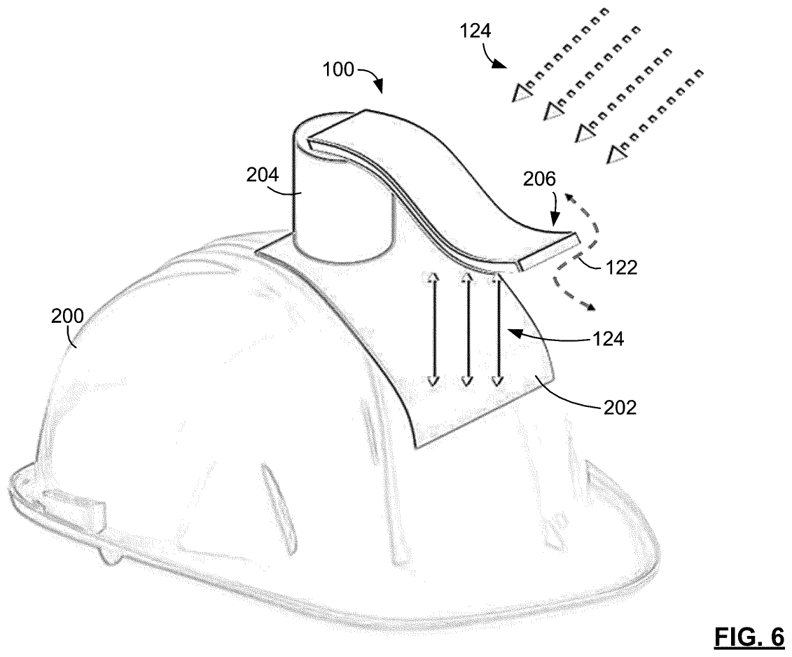

Referring now to FIGS. 6 to 10B, the energy harvesting system 128 is light weight, easy to install, and flexibility. In some embodiments, the energy harvesting system 128 is integrated into clothing, headgear, footwear, or other wearable devices.

Referring to FIG. 6, the energy harvester 100 is mounted to a helmet 200. In some embodiments, the energy harvester 100 is mounted in a position spaced from an external surface 202 formed by the helmet 200. The surface 202 may be a reflective surface to direct light 124 back at an underside of the harvester 100. All or only a portion of the outside surface of the helmet 200 may be reflective. The reflective surface 202 is formed of a light reflective material, such as aluminum foil and/or silver.

In some embodiments, the harvester 100 is secured to the helmet 200 via a spacer 204, such as a pillar. The pillar may be a cylindrical, rectangular or square pillar. The pillar may be located in the center of the outside of the helmet. One or more dimensions of the spacer 204 are selected to raise the energy harvester 100 and avoid collision between the helmet 200 and the energy harvester 100 (e.g., a tip 206 farthest from where the harvester 100 is anchored). Upon movement of the wearer, vibrations 122 oscillate the energy harvester 100 up and down with the frequency of the wearer, generating electricity.

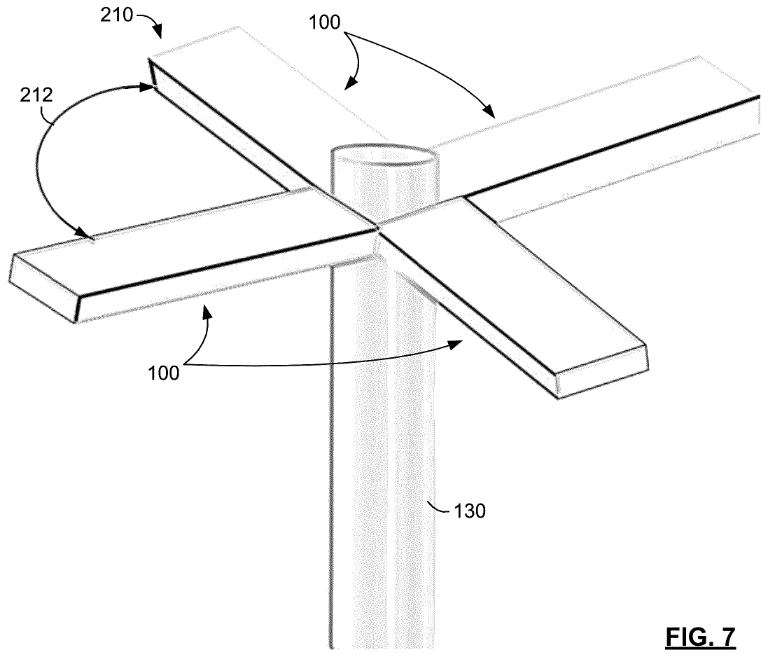

Referring to FIG. 7, in some embodiments, energy harvesters 100 may be formed into an array 210. The array 210 includes a plurality of energy harvesters 100 anchored to a common fixture 130. The fixture 130 may be, e.g., a spacer 204 such as a pillar. In some embodiments, a distance 212 individual energy harvesters 100 in the array 210 is selected to influence the oscillation frequency of each harvester 100. In some embodiments, the distance 212 is selected to enhance overall efficiency.

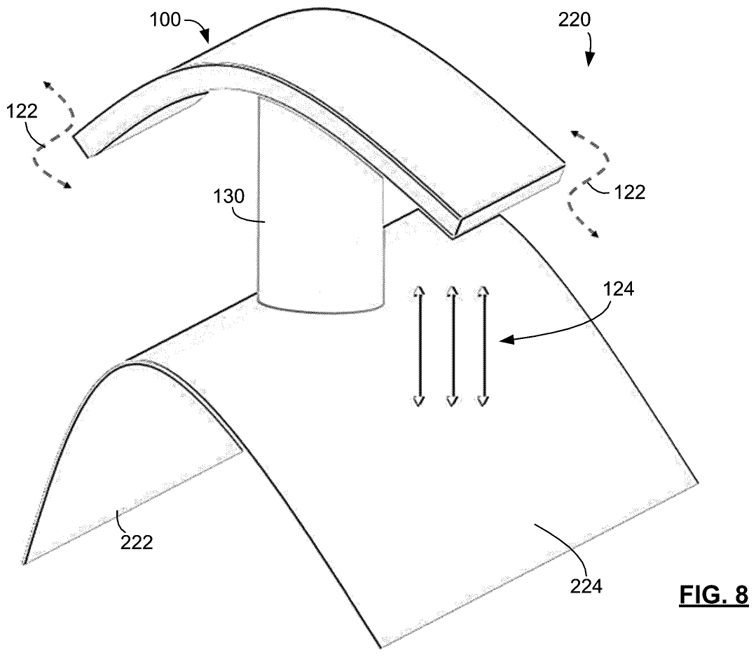

Referring to FIG. 8, an energy harvester assembly 220 is illustrated. The assembly 220 includes an energy harvester 100 mounted to a fixture 130 supported by a base 222.

In some embodiments, the base 222 is a clip for securing the harvester 100 to another device. Accordingly, the assembly 220 may mounted to a device or worn by a user. The illustrated example base 222 is a U-shaped base with elastic properties. Consequently, the illustrated example U-shaped base 222 functions as a clip for securing the energy harvester 100. In some embodiments, the base 222 is a shoulder mount. The example base 222 has elastic properties to expand according to a wearer's shoulder size. Such a configuration can be worn on the shoulder of the wearer.

The base 222 forms an opposing surface 224 directed towards the harvester 100. The surface 224 is reflective to direct light to an underside of the harvester 100.

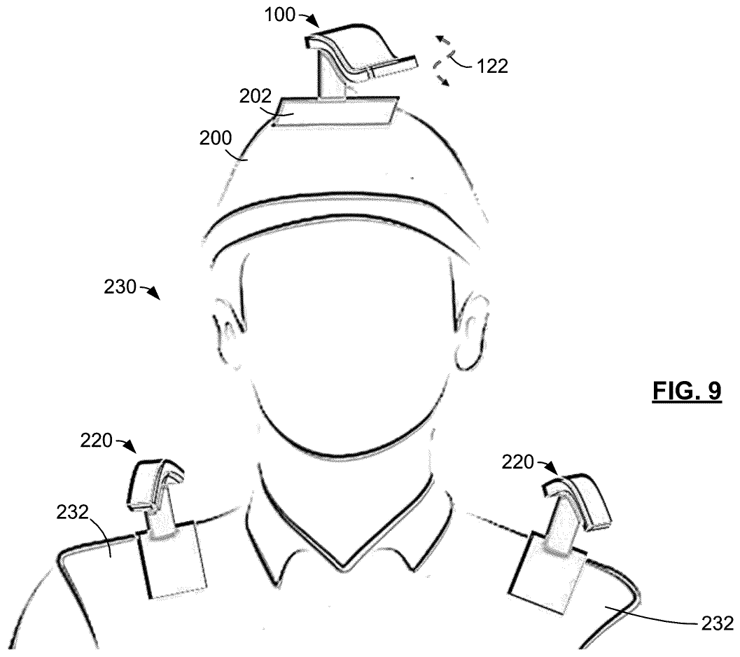

Referring to FIG. 9, a wearer 230 may wear a headpiece with a mounted energy harvester 100 and one or more assemblies 220 on their shoulders 232. Thus, the walking of the wearer 230 generates vibrations that will be converted into electricity by the piezoelectric layers of the energy harvesters 100. If there is light in the environment, the photovoltaic layers of the energy harvesters 100 convert the light into electricity

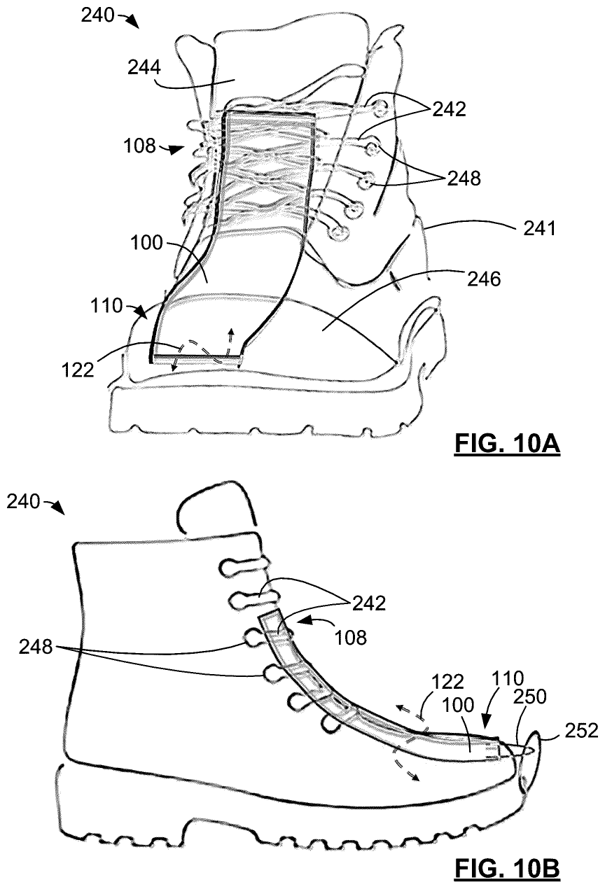

Referring to FIG. 10A, the energy harvester 100 is mounted to a top of a body 241 of a shoe 240. In the illustrated example, one end 108 of the energy harvester 100 is positioned under the laces 242 (e.g., extending through eyelets 248) against the tongue 244 and the fastened laces 242 act as the fixture 130 to hold the energy harvester 100 firmly in place while its other end 110 is free to move (e.g., laying against toe cap 246 when at rest). In such an arrangement, each step of the wearer causes the energy harvester 100 to deflect up and down and ultimately generate electricity, while the surface of the energy harvester 100 can generate electricity from light.

Referring to FIG. 10B, the energy harvester 100 may be secured at both of opposite ends 108, 110. This is referred to as a clamped-clamped device herein. In the illustrated example, to provide easy installation, one end 110 of the energy harvesting device is incorporated with a snap hook 250. The snap hook 250, in conjunction with a ring 252, which is permanently fixed to the farthest point of the toe cap, can be used to anchor and tighten the energy harvester 100 while the other side is secured with the shoelaces 242. Upon movement of the wearer, the center of energy harvester 100 between the ends 108, 110 experiences a maximum deflection. This configuration may increase the durability of the energy harvester 100 (e.g., useful when movement occurs at high frequencies).

1. An energy harvester, comprising a flexible layered sheet having an upper face on an upper side and a lower face opposite the upper face on a lower side, the flexible layered sheet including a first photovoltaic layer at the upper end, a second photovoltaic layer at the lower end, and first and second piezoelectric layers between the first and second photovoltaic layers, whereby vibration of the energy harvester results in the generation of electricity and exposure of the energy harvester to light results in the generation of electricity.

2. The energy harvester of claim 1, further comprising a first adhesive layer between the first photovoltaic layer and the first piezoelectric layer, a second adhesive layer between the first piezoelectric layer and the second piezoelectric layer, and a third adhesive layer between the second piezoelectric layer and the second photovoltaic layer.

3. The energy harvester of claim 2, wherein the adhesive layers are formed to produce a desired operating frequency and flexibility of the energy harvester by controlling Young's modulus of the adhesive layers through the selection of a mixture of different materials or the temperature, pressure and duration of curing.

4. The energy harvester of claim 3, wherein thicknesses and porosity of the adhesive layers are selected to produce a desired flexibility of the adhesive layers by increasing the porosity and reducing the thickness to produce greater flexibility and lower operating frequency and reducing the porosity and increasing the thickness to produce reduced flexibility and higher operating frequency.

5. The energy harvester of claim 1, wherein the first and/or second piezoelectric layers are operable mode 33.

6. The energy harvester of claim 1, wherein the first and/or second piezoelectric layers are operable mode 31.

7. The energy harvester of claim 1, further comprising a protective layer surrounding the sheet to protect from environmental impacts and increase durability.

8. The energy harvester of claim 1, wherein the energy harvester comprises both transparent and non-transparent electrodes, the transparent electrodes arranged to pass light to the active layer, the non-transparent electrodes arranged to reflect light to the active layer.

9. The energy harvester of claim 1, wherein the energy harvester comprises organic materials, the organic materials deposited by thermal evaporation or solution-based processes.

10. The energy harvester of claim 1, wherein materials used to construct the energy harvesting system are selected such that the energy harvester is light and flexible, incorporating a polymer-based or plastic layer serving as a substrate.

11. An energy harvester system comprising the energy harvester of claim 1 secured to a fixture and coupled to a power management system.

12. The energy harvester system of claim 13, wherein the energy harvester is secured at one end thereof to the fixture while the opposing end is unsecured to move freely.

13. An array comprising the energy harvester system of claim 12 with a plurality of energy harvesters secured to the fixture and coupled to the power management system.

14. A helmet comprising the energy harvester of claim 1 mounted to a helmet.

15. An assembly comprising the energy harvester of claim 1 mounted to a base, the base being U-shaped and formed of a material with elastic properties and shaped to be fitted to a wearer's shoulder.

16. A shoe comprising the energy harvester of claim 1 secured at one end thereof to a body of the shoe by laces of the shoe while an opposite end is unsecured to move freely.

17. A shoe comprising the energy harvester of claim 1 secured at each of first and second opposing ends to a body of the shoe.

18. The energy harvester of claim 1, mounted to a base and spaced from a reflective outside surface of the base, to receive reflected light from the reflective outside surface on an underside of the harvester that is directed towards the reflective outside surface.

19. The energy harvester of claim 18, wherein the base is a helmet or a clip.

20. The energy harvester of claim 1, integrated with CMOS circuitry to rectify and regulate harvested voltage and/or current.
